(19) United States
(12) Patent Application Publication
(10) Pub. No.: US 2025/0211167 A1
(43) Pub. Date: Jun. 26, 2025

(54) DEGRADATION FACTOR ESTIMATION DEVICE, DEGRADATION FACTOR DIAGNOSIS METHOD

(71) Applicant: Hitachi, Ltd., Tokyo (JP)

(72) Inventors: Toru KOUNO, Tokyo (JP); Jun TSUNODA, Tokyo (JP)

(73) Assignee: Hitachi, Ltd., Tokyo (JP)

(21) Appl. No.: 18/940,286

(22) Filed: Nov. 7, 2024

(30) Foreign Application Priority Data
Dec. 20, 2023 (JP) 2023-214536

(51) Int. Cl. H02S 50/10; G01R 27/02

(52) U.S. Cl. CPC H02S 50/10; G01R 27/02

(57) ABSTRACT

The present invention aims to provide a diagnostic technique capable of estimating local degradation of the series resistance included in a solar cell. A solar cell system according to the present invention acquires the series resistance of the solar cell when the solar cell limits output based on the first amount of solar radiation, acquires the series resistance of the solar cell when the solar cell tracks a maximum power point, and uses these series resistances to diagnose whether a degradation factor of the solar cell is a local increase in the series resistance or a total increase in the series resistance.

### TECHNICAL FIELD

The present invention relates to a technology for diagnosing the degradation factors of solar cells.

### BACKGROUND ART

A decrease in shunt resistance is considered a degradation factor of solar cells. The degree of degradation of a solar cell can be estimated by estimating the degradation due to a decrease in shunt resistance. Various methods have been proposed to estimate degradation due to decreased shunt resistance.

The following patent literature 1 aims to “accurately grasp the degradation of the filler in the solar cell module and the degradation of the solar cell itself by accurately finding the amount of reduction in shunt resistance from the IV characteristics of the solar cell affected by other factors such as fluctuations in solar radiation and errors in the measuring instrument” and describes a technology in which “a parallel resistance calculation device of the present invention uses a provisional resistance value of the parallel resistance to calculate the reverse saturation current of the diode part of the solar cell, and repeats the calculation while varying the provisional resistance values until the reverse saturation current matches a predetermined value” (see Abstract).

### CITATION LIST

### Patent Literature

Patent Literature 1: Japanese Unexamined Patent Application Publication No. 2020-202730

### SUMMARY OF INVENTION

### Technical Problem

A conventional degradation factor estimation method such as that in patent literature 1 estimates the degradation of a solar cell by estimating the degradation due to a decrease in shunt resistance. However, the inventors have found that the actual degradation cases of solar cells include some cases where the performance of the solar cell may be degraded due to local degradation of the series resistance included in the solar cell. It is difficult to estimate the local degradation of the series resistance using the conventional technique of estimating degradation due to a decrease in shunt resistance such as that in patent literature 1.

The present invention has been made in consideration of the above-described problems and aims to provide a diagnostic technique capable of estimating local degradation of the series resistance included in a solar cell.

### Solution to Problem

The solar cell system according to the present invention acquires the series resistance of a solar cell when the solar cell limits output based on the first amount of solar radiation, acquires the series resistance of the solar cell when the solar cell tracks a maximum power point, and uses these series resistances to diagnose whether a degradation factor of the solar cell is a local increase in the series resistance or a total increase in the series resistance.

### Advantageous Effects of Invention

The solar cell system according to the present invention can estimate local degradation of the series resistance included in the solar cell. Problems, configurations, and effects, for example, other than those described above will become clear from the description of the following embodiments.

### BRIEF DESCRIPTION OF DRAWINGS

FIG. 1A illustrates the structure of a solar cell panel 1;

FIG. 1B illustrates the structure of the solar cell panel 1;

FIG. 2 illustrates the current-voltage characteristics of the solar cell;

FIG. 3A illustrates the front and back views of the solar cell;

FIG. 3B is the equivalent circuit diagram of a solar cell module;

FIG. 4A illustrates another configuration of the solar cell module;

FIG. 4B illustrates another configuration of the solar cell module;

FIG. 5A illustrates the process of replacing the solar cell module with an equivalent circuit to analyze the operations;

FIG. 5B illustrates the process of replacing the solar cell module with the equivalent circuit to analyze the operations;

FIG. 5C illustrates the process of replacing the solar cell module with the equivalent circuit to analyze the operations;

FIG. 6 illustrates the equivalent circuit in FIG. 5C decomposed based on the superposition theorem;

FIG. 7A illustrates the result of analyzing operations on the equivalent circuit of the solar cell module;

FIG. 7B illustrates the result of analyzing operations on the equivalent circuit of the solar cell module;

FIG. 7C illustrates the result of analyzing operations on the equivalent circuit of the solar cell module;

FIG. 8A illustrates the vicinity of the maximum power point in the current-voltage characteristics of the solar cell;

FIG. 8B illustrates the current-voltage characteristics when the series resistance increases locally;

FIG. 9 illustrates the time-dependent change in the output power of the solar cell;

FIG. 10 illustrates the current-voltage characteristics and the power-voltage characteristics when the solar cell output is suppressed;

FIG. 11 is a flowchart explaining the procedure to diagnose the degradation factor of the solar cell;

FIG. 12 is a flowchart explaining the procedure to calculate a first series resistance R1 and a first loss;

FIG. 13 is a flowchart explaining the procedure for a control device 100 to rank the quality of the solar cell based on the solar cell diagnosis result;

FIG. 14 is a configuration diagram of a solar cell system according to a second embodiment; and

FIG. 15 is an example screen as a user interface provided by the control device 100.

### DESCRIPTION OF EMBODIMENTS

### First Embodiment

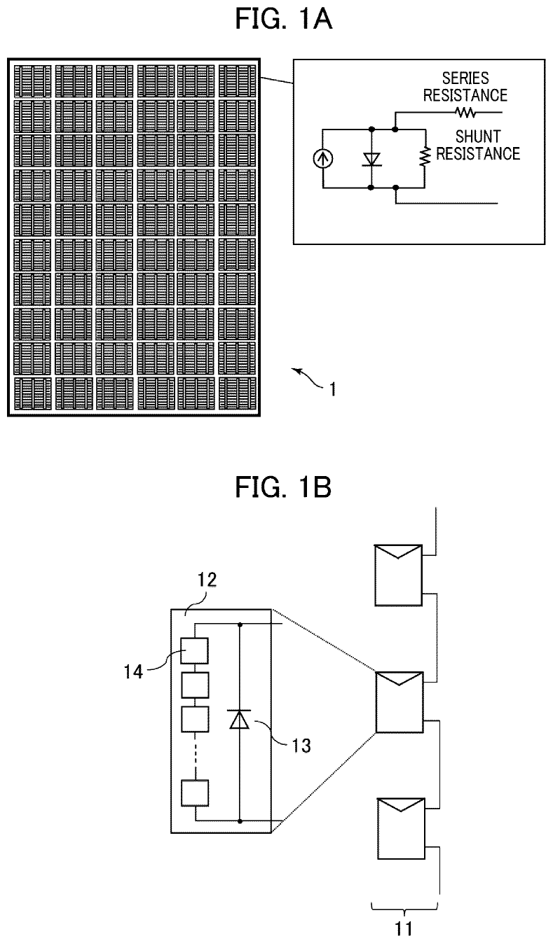

FIGS. 1A to 1B illustrate the structure of a solar cell panel 1. The solar cell panel 1 is formed by arranging solar cell modules 12. A solar cell string 11 is formed by connecting the solar cell modules 12 in series and bypassing each solar cell 14 through the use of a bypass diode 13. The solar cell module 12 is formed by connecting the solar cells 14 in series. The equivalent circuit of the solar cell 14 includes a current source, a pn junction diode, shunt resistance (parallel resistance), and series resistance. The current source supplies a current proportional to the amount of solar radiation. If any solar cell 14 in the solar cell module 12 fails, the failed solar cell module 12 is bypassed by the bypass diode 13.

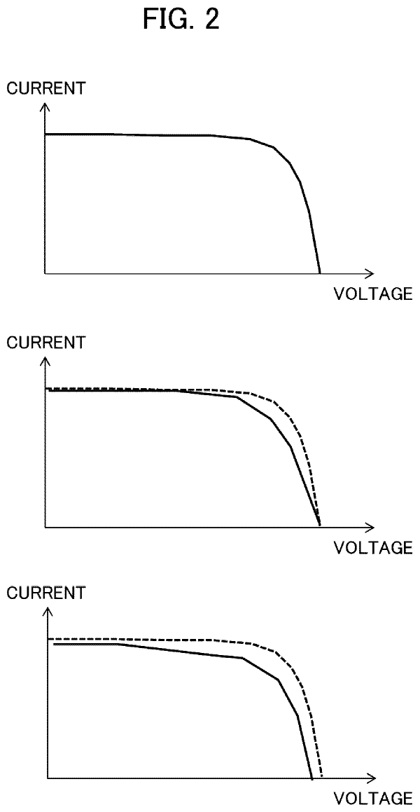

FIG. 2 illustrates the current-voltage characteristics of a solar cell. The solar cell 14, the solar cell module 12, the solar cell string 11, and the solar cell panel 1 all exhibit similar characteristics, so hereinafter they will be simply referred to as solar cells unless they are explicitly distinguished.

The top of FIG. 2 illustrates the current-voltage characteristics (characteristics of an output current and an output voltage) of a normal solar cell. The middle of FIG. 2 illustrates the current-voltage characteristics when the series resistance increases totally due to degradation. Compared to the normal case, the plots around the maximum power point totally decrease, resulting in a decrease in the maximum output. The bottom of FIG. 2 illustrates the current-voltage characteristics when the shunt resistance decreases due to degradation. Similar to the middle of FIG. 2, the plots around the maximum power point totally decrease in comparison with the normal case. The short-circuit current and the open-circuit voltage also decrease in comparison with the normal case.

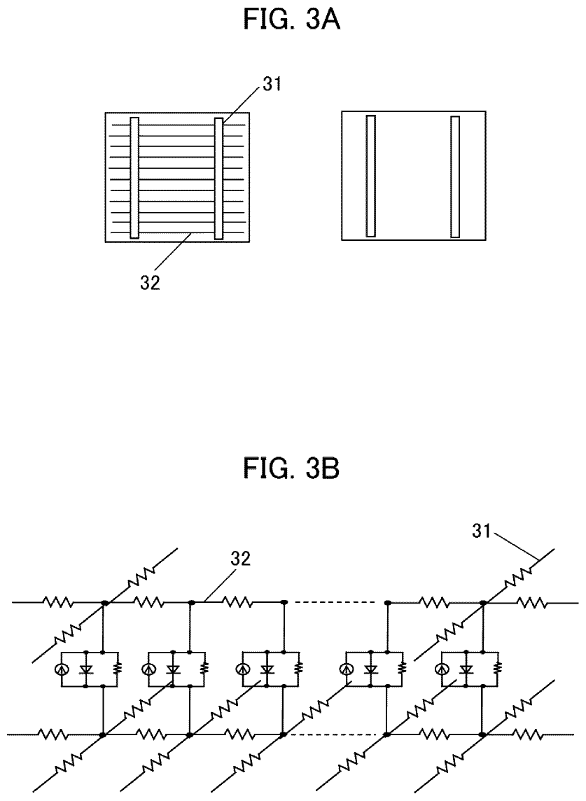

FIG. 3A illustrates the front and back views of a solar cell. A bus-bar 31 and a finger 32 are placed on the front surface of the solar cell. A back resistance is planarly placed on the back surface of the solar cell.

FIG. 3B is the equivalent circuit diagram of a solar cell module. The finger 32 can be expressed as a series connection of the series resistance of the solar cell. The solar cell is placed between the finger 32 on the front surface and the back resistance. The bus-bar 31 extends in a direction perpendicular to the finger 32 at the contact point between the solar cell and the finger 32. FIGS. 3A and 3B show an example using two bus-bars 31.

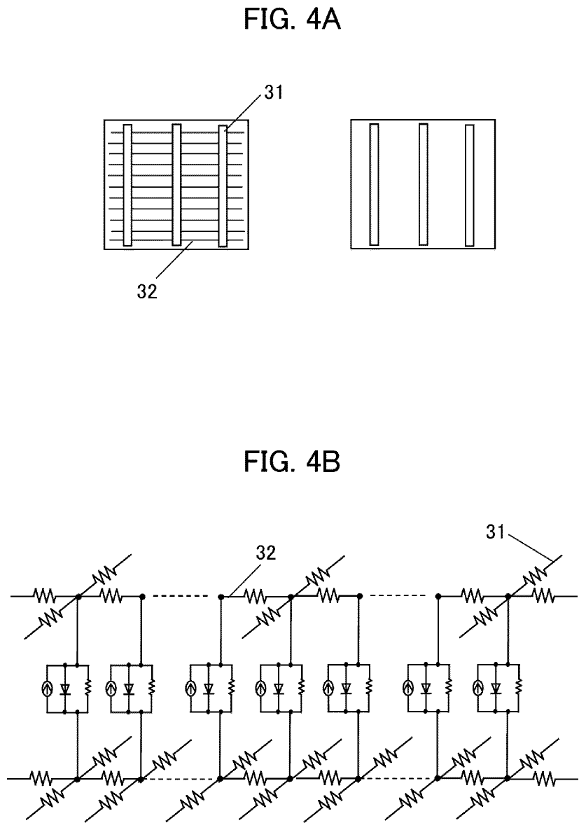

FIGS. 4A and 4B illustrate another configuration of the solar cell module. Unlike FIGS. 3A and 3B, three bus-bars 31 are placed on the surface of the solar cell module. The rest of the configuration is similar to FIGS. 3A and 3B.

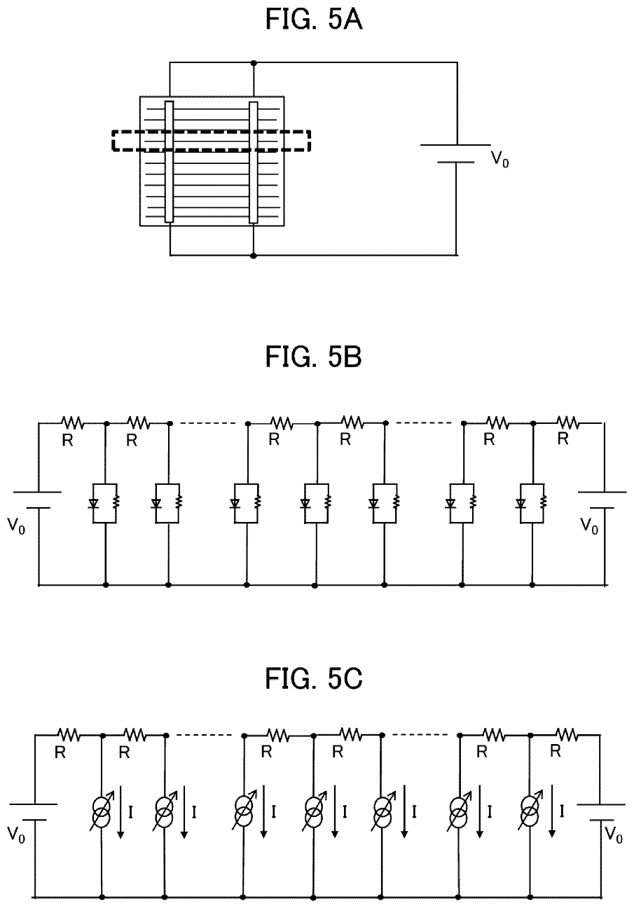

FIGS. 5A through 5C illustrate the process of replacing the solar cell module with an equivalent circuit to analyze the operations. Voltage V0 between both ends is connected to the solar cell module and the area enclosed by the broken line in FIG. 5A is targeted at the analysis. FIG. 5B is an equivalent circuit diagram corresponding to the broken line area in FIG. 5A. To simplify the analysis, a current source replaces the parallel connection of the diode and the shunt resistance of the solar cell as illustrated in FIG. 5C.

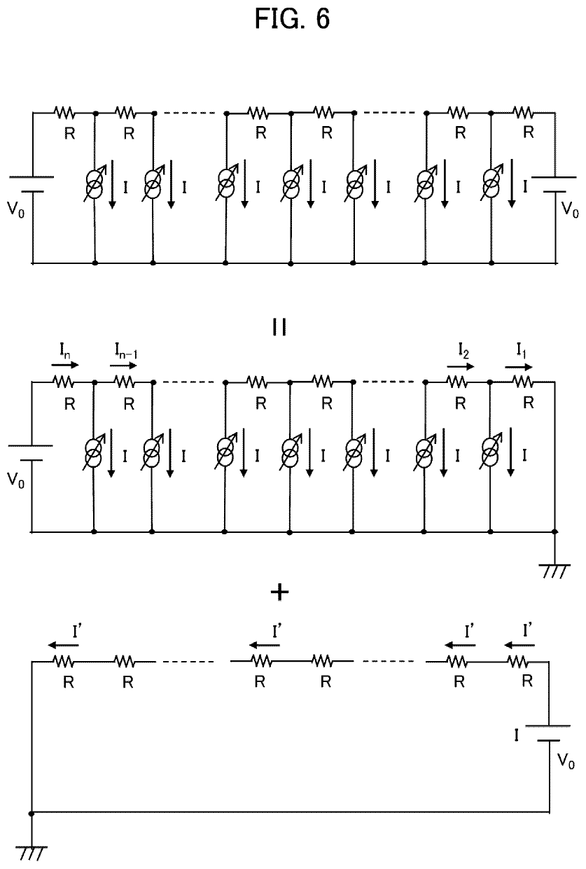

FIG. 6 illustrates the equivalent circuit in FIG. 5C decomposed based on the superposition theorem. The top of FIG. 6 illustrates an equivalent circuit of FIG. 5C. This equivalent circuit can be expressed by superposing the current supplied from a power supply on the left and the current supplied from a power supply on the right (superposition theorem). FIG. 6 schematically illustrates the superimposition of operations on the partial circuits.

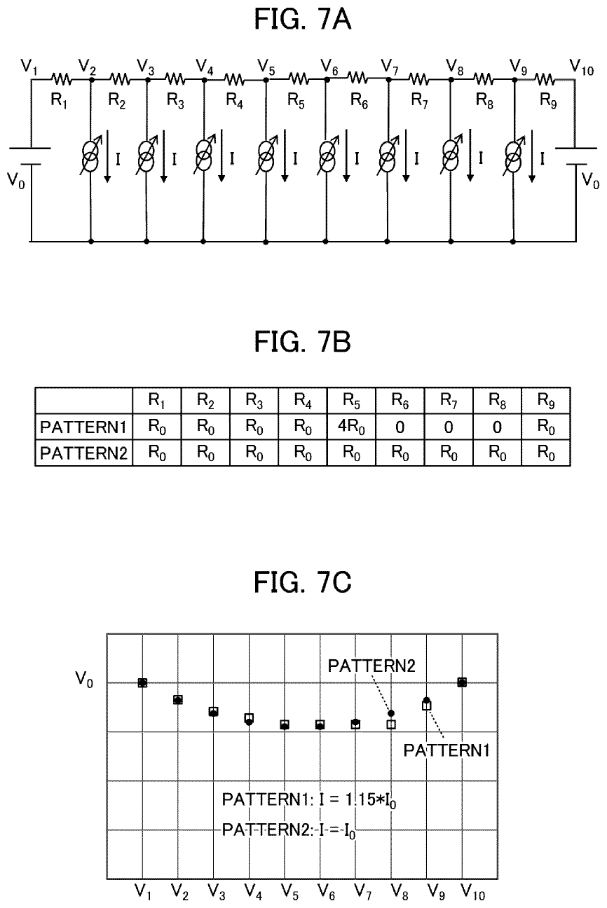

FIGS. 7A to 7C illustrate the result of analyzing operations on the equivalent circuit of the solar cell module. The analysis uses the superposition theorem illustrated in FIG. 6. FIG. 7A is an equivalent circuit diagram corresponding to the top of FIG. 6. As illustrated in FIG. 7A, the series resistances are sequentially denoted R1 through R9 from the left, and potentials between both ends of the series resistances are sequentially denoted V1 through V10 from the left.

FIG. 7B illustrates two degradation patterns of the series resistance. The total resistance of the solar cell module is the same in all patterns. Pattern 1 is a degradation pattern in which only R5 increases fourfold and R6 through R8 become 0, resulting in a local increase in the series resistance. Pattern 2 shows that all series resistances evenly increase (degrade).

FIG. 7C illustrates the results of analyzing operations on the solar cell module based on patterns 1 and 2. The analysis results show that potentials V1 through V10 are roughly the same between patterns 1 and 2, and a current flowing through each diode is larger in pattern 1 than in pattern 2.

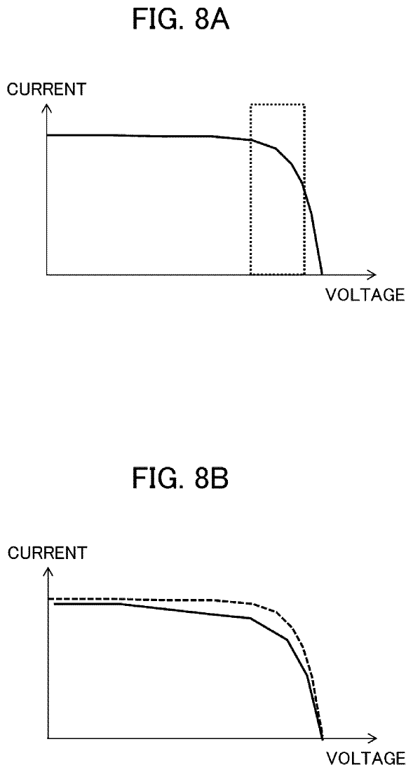

FIG. 8A illustrates the vicinity of the maximum power point in the current-voltage characteristics of a solar cell. A low battery voltage turns off the diodes in the equivalent circuit of the solar cell and further decreases the voltage. Contrastingly, an increased battery voltage changes the diodes from OFF to ON. The vicinity of the maximum power point corresponds to this voltage region. In other words, when the solar cell is operating near the maximum power point, the diodes may frequently turn on and off randomly due to fluctuations in the battery voltage.

FIG. 8B illustrates the current-voltage characteristics when the series resistance increases locally. When the series resistance increases locally, unlike the case where the series resistance increases totally as illustrated in the middle of FIG. 2, the current-voltage characteristics are similar to those when the shunt resistance decreases as described in the bottom of FIG. 2. This feature can be used to detect local increases in the series resistance.

As explained in FIG. 7C, when the series resistance increases locally, the current flowing through the diodes of the battery cell equivalent circuit increases totally, and as a result, the output current from the battery cell decreases. This is because the output current is found by subtracting the diode current from the output of the current source. Near the maximum power point, the application of more current to the diodes tends to cause insufficient voltage between both ends of the diode, and as a result, more diodes are turned off (see the explanation in FIG. 8A), causing an overall depression in the current-voltage characteristics. As a result of the above, the vicinity of the maximum power point shows the IV characteristics as illustrated in the upper right of FIG. 8B and the IV characteristics totally decrease the currents in the other current regions.

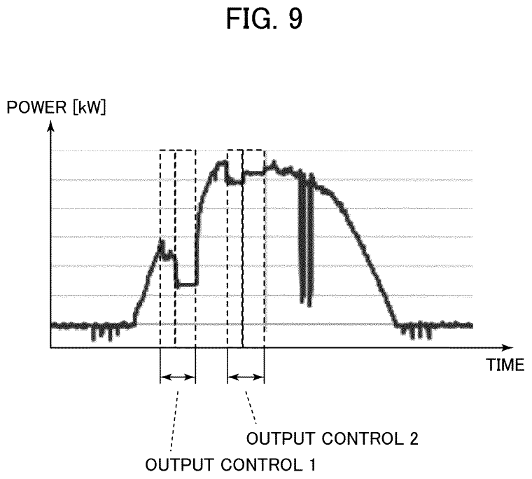

FIG. 9 illustrates the time-dependent change in the output power of a solar cell. In principle, the output power of a solar cell increases as the amount of solar radiation increases, but there are cases where the output power is intentionally suppressed to be consistent with a prior power generation plan, for example. FIG. 9 illustrates an output power when such output suppression is performed. In this example, output suppression is performed twice, and the latter uses a larger amount of solar radiation. The description below explains a method for estimating the degradation factors of the solar cell by using the battery characteristics during the two output suppressions.

As above, the vicinity of the maximum power point tends to randomly repeat turning on and off the equivalent diodes and it is unfavorable to use this region for the diagnosis. Therefore, the diagnosis uses a more stable operating voltage region. Specifically, it is considered favorable to use measurement values when the battery is operating (namely, when the output is suppressed) under the control of a device (such as a converter) that controls the battery. In the region where the battery voltage is low, however, the voltage drop is small as illustrated in the middle and the bottom of FIG. 2, making it difficult to acquire data usable for the diagnosis. As a result of the above, the present invention diagnoses the degradation factors by using the measurement values when the solar cell output is suppressed.

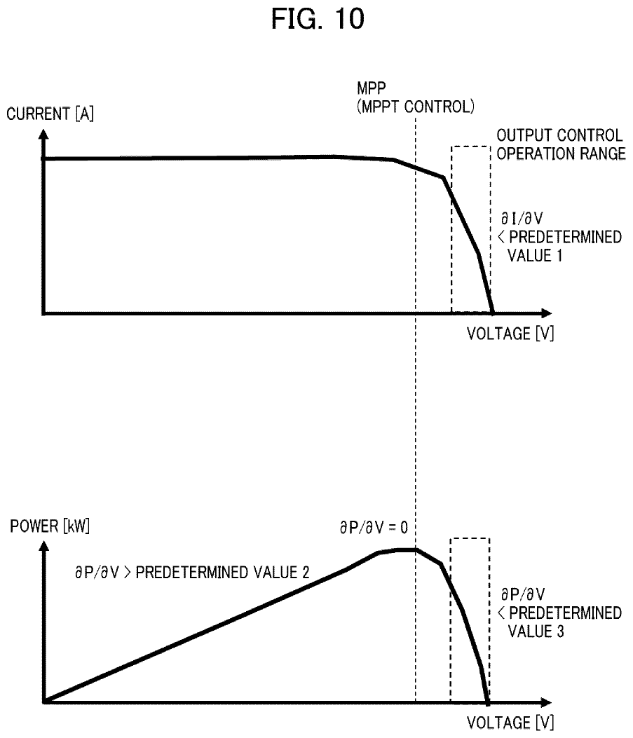

FIG. 10 illustrates the current-voltage characteristics and the power-voltage characteristics when the solar cell output is suppressed. When the output of the solar cell is suppressed, the solar cell is operated in a voltage region that causes a negative value resulting from differentiating the power with the voltage in the power-voltage characteristics. This condition is defined as ∂P/∂V<predetermined value 3. This voltage region corresponds to a voltage region that causes a negative value resulting from differentiating the current with the voltage in the current-voltage characteristics. This condition is defined ∂P/∂V<predetermined value 1. Furthermore, the maximum power point corresponds to a voltage region that causes a value of approximately 0 (within a predetermined range around 0) resulting from differentiating the power with the voltage in the power-voltage characteristics.

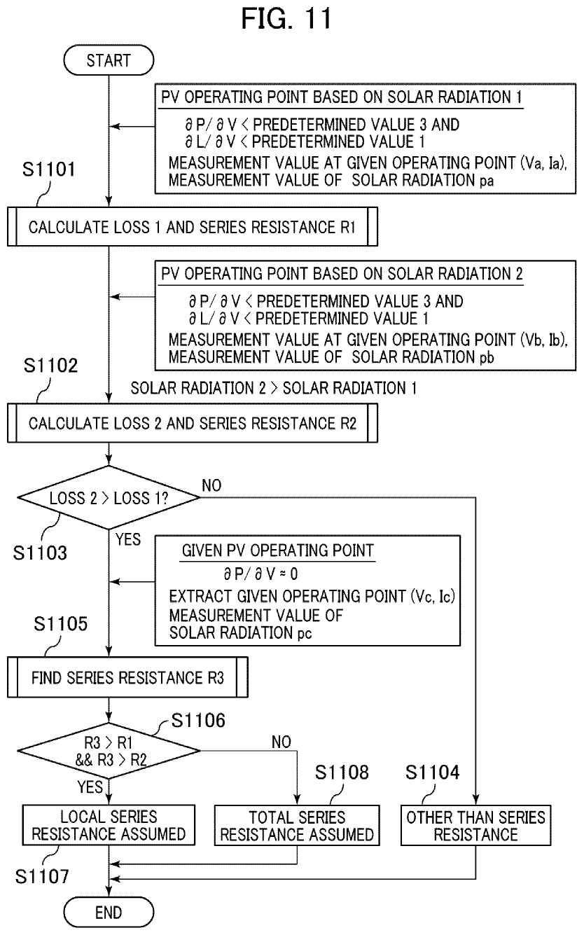

FIG. 11 is a flowchart explaining the procedure to diagnose the degradation factor of the solar cell. This flowchart can be implemented by a control device 100 (f portion 110) described below, for example. The description below explains each step in FIG. 11.

### (FIG. 11: Step S1101)

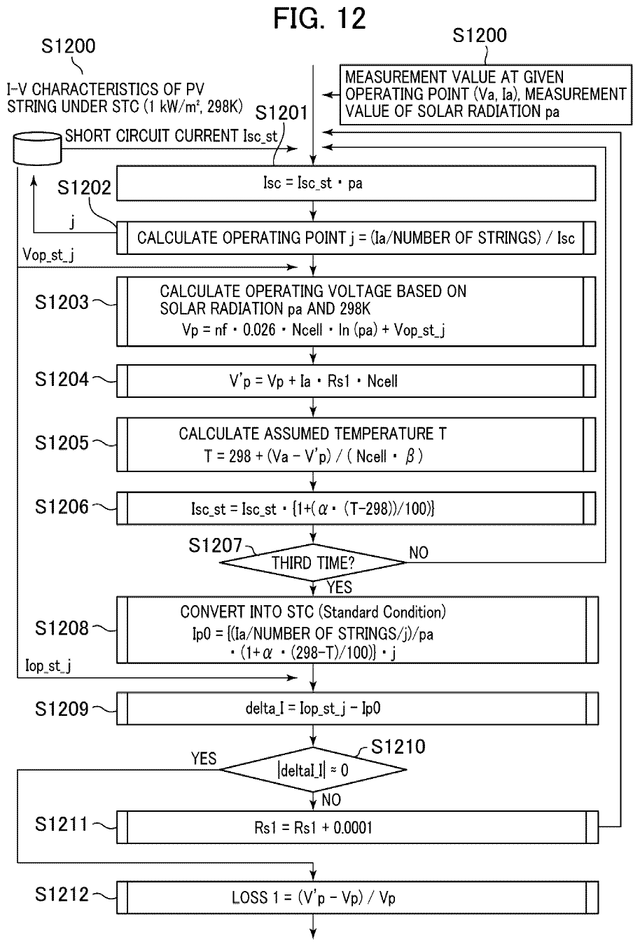

The control device 100 acquires the measurement value at a given operating point (output voltage, output current)=(Va, Ia) and the measurement value of the amount of solar radiation pa when the solar cell controls outputs as illustrated in FIGS. 9 and 10 based on a first amount of solar radiation. The power-voltage characteristics and the current-voltage characteristics during the output control shall satisfy the conditions described in FIG. 10. The control device 100 uses the acquired measurement values to calculate the first loss and the first series resistance R1 of the solar cell according to the procedure in FIG. 12 described below.

### (FIG. 11: Step S1102)

The control device 100 acquires the measurement value at a given operating point (output voltage, output current)=(Vb, Ib) and the measurement value of the amount of solar radiation pb when the solar cell controls outputs as illustrated in FIG. 9 through FIG. 10 based on a second amount of solar radiation greater than the first amount of solar radiation. The power-voltage characteristics and the current-voltage characteristics during the output control shall satisfy the conditions described in FIG. 10. The control device 100 uses the acquired measurement values to calculate the second loss and the second series resistance R2 of the solar cell according to the procedure illustrated in FIG. 12 described below.

### (FIG. 11: Step S1103 to S1004)

If the second loss is smaller than or equal to the first loss (S1003: No), the control device 100 diagnoses that the degradation factor of the solar cell is not an increase in the series resistance (S1004). If the second loss is greater than the first loss, proceed to S1105.

### (FIG. 11: Step S1105)

The control device 100 acquires the measurement value at a given operating point (output voltage, output current)=(Vc, Ic) near the maximum power point and the measurement value of the solar radiation pc. The power-voltage characteristics at the maximum power point shall satisfy the conditions described in FIG. 10. The control device 100 uses the acquired measurement value to calculate the maximum power point resistance R3 of the solar cell according to the procedure illustrated in FIG. 12 described below. R3 is the series resistance when the solar cell is operating to track the maximum power point.

### (FIG. 11: Step S1106 to S1008)

If R3 is greater than R1 and R3 is greater than R2 (S1106: Yes), the control device 100 diagnoses that the degradation factor is a local increase in the series resistance of the solar cell (S1107). Otherwise, the degradation factor is assumed to be a total and uniform increase in the series resistance of the solar cell (S1108).

### (FIG. 11: Step S1106 to S1008: Supplement)

These steps determine whether R3>R1 and R3>R2 are true, but it may be also favorable to perform the same diagnosis as in S1107 and S1108 if only one of R3>R1 or R3>R2 is true. This is because the values of R1 and R2 are often close to each other. However, the diagnosis accuracy is considered to be more improved when both R3>R1 and R3>R2 are true.

FIG. 12 is a flowchart explaining the procedure to calculate a first series resistance R1 and a first loss. The same procedure can be used to calculate the second series resistance R2, the second loss, and the maximum power point resistance R3. This flowchart can be implemented by a control device 100 (arithmetic portion 110) described below, for example. The description below explains each step in FIG. 12.

### (FIG. 12: Step S1200)

The control device 100 acquires the measurement value at the operating point (Va, Ib) and the measurement value of the amount of solar radiation pa. The control device 100 further acquires specification data describing the specification values of the solar cell. The specification data describes the following specification values. (a) Short-circuit current I_{SC_ST}, (b) Open voltage V_{OC_ST}, (c) Optimum operating current I_{OP_ST}, (d) Optimum operating voltage V_{OP_ST}, and (e) Coefficients α and β in the calculation formula described below. α denotes the temperature characteristics [%/° C.] of the short circuit current, and β denotes the temperature characteristics [mV/° C.] of the operating voltage. The specification data may be acquired from a power conditioner to drive the solar cell or may be previously stored in a storage device included in the control device 100, for example. Other appropriate measures may be used to acquire the specification data.

### (FIG. 12: Step S1200: Supplement)

The specification data, (c) optimum operating current I_{OP_ST} and (d) optimum operating voltage V_{OP_ST}, can be previously described in the data for each operating point j described below. Alternatively, these values may be calculated for each operating point j. The values at operating point j are described as: (c) optimum operating current I_{OP_ST_j} and (d) optimum operating voltage V_{OP_ST_j}.

### (FIG. 12: Step S1201)

The control device 100 calculates the short-circuit current I_{SC} as I_{SC_ST}·pa.

### (FIG. 12: Step S1202)

The solar radiation amount pa can be expressed as the ratio of the short-circuit current based on the amount of present solar radiation to the short-circuit current I_{SC_ST} based on the amount of standard solar radiation. Since the presently operating current based on the amount of present solar radiation is Ia, the short-circuit current based on the amount of present solar radiation can be defined as Ia/j. Therefore, the amount of solar radiation pa is expressed as (short-circuit current based on the amount of present solar radiation)/I_{SC_ST}, namely, the equation: pa=(Ia/j)/I_{SC_ST}. This equation can be transformed to j=(Ia/pa)/I_{SC_ST}. Furthermore, the equation at S1201 is substituted to yield j=(Ia)/I_{SC}. The number of strings for the solar cell is considered to yield j=(Ia/number of strings)/I_{SC}. The control device 100 implements the operating point j based on the above procedure.

### (FIG. 12: Step S1203)

The control device 100 uses kT/q=0.026 at 298K to calculate operating voltage V_{P} for the amount of solar radiation pa and battery temperature T=298K according to the following equation. T: absolute temperature [K] of the solar cell, k: Boltzmann constant, q: charge amount [C] of electrons, nf: junction constant, and N_{cell}: the number of cells.

$$( Fig . 12 : Step S 1203 : Equation )$$

$${V}_{p} = {n}_{f} \cdot 0.026 \cdot {N}_{cell} \cdot In ( pa ) + {V}_{OP\_ST \_j}$$

### (FIG. 12: Step S1204)

The series resistance per cell is expressed as Rs1. The control device 100 calculates voltage drop V′p due to Rs1 using the equation: V′p=Vp+Ia·Rs1·Ncell. The meaning of V′p will be explained in S1205.

### (FIG. 12: Step S1205)

The control device 100 calculates assumed temperature T of the solar cell according to the following equation. B generally denotes the temperature characteristics of silicon, and is approximately equal to −2 mV/K. V′p is assumed series resistance Rs1 replaced with a voltage drop based on the same (assumed voltage drop). In other words, the following equation calculates assumed temperature T based on a difference between measured voltage Va and the assumed voltage drop.

$$( Fig . 12 : Step S 1205 : Equation )$$

$$T = 298 + ( {V}_{PE} - {V}_{p}^{′} ) / ( {N}_{cell} \cdot β )$$

### (FIG. 12: Step S1206)

The control device 100 updates short-circuit current I_{SC_ST} according to the following equation.

$$( Fig . 12 : Step S 1206 : Equation )$$

$${I}_{SC\_ST} = {I}_{ST\_ST} \cdot \{ 1 + ( α \cdot ( T - 298 ) ) / 100 \} \}$$

### (FIG. 12: Step S1207)

The control device 100 repeats steps S1202 through S1206 a predetermined number of times (such as three times) and then proceeds to step S1208, or, otherwise, performs S1206 and then returns to S1202.

### (FIG. 12: Step S1208)

The control device 100 converts the operating current Ia into a value (I_{P0}) under the condition of the amount of standard solar radiation and standard temperature (STC: Standard Condition) according to the following equation.

$$\begin{matrix}( Fig . 12 : Step S 1208 : Equation ) & \end{matrix}$$

$${I}_{P 0} = \{ ( Ia / number of strings / j ) / pa \cdot ( 1 + α \cdot ( 298 - T ) / 100 ) \} \cdot j$$

### (FIG. 12: Step S1209 to S1211)

The control device 100 calculates a difference delta_I between I_{P0} calculated at S1208 and standard operating current I_{OP_ST_j}. If delta_I is small enough, proceed to S1212, or, otherwise, increment Rs1 (by 0.0001 for example) and return to S1202.

### (FIG. 12: Step S1212)

The control device 100 calculates the first loss=(V′p−Vp)/Vp.

### First Embodiment: Derivation of Calculation Equation at S1203

The solar cell can be expressed by the following equation 1.

I=Isc·p−Is·{exp((q·(V/N_{cell}))/(nf·k·T))} (1)

The following equation 3 can express Vₚ when equation 1 uses I_{SC}=I_{SC_ST}, KT/q=0.026 at 298K, and I=I_{SC_ST}·p·j.

$${V}_{p} = {n}_{f} \cdot 0.026 \cdot ln ( ( ( 1 - j ) \cdot {I}_{SC\_ST} \cdot p ) / Is ) \qquad ( 3 )$$

The following equation 4 expresses the standard operating voltage V_{OP_ST} under the condition of p=1.0.

$${V}_{OP\_ST} = {n}_{f} \cdot 0.026 \cdot ln ( ( ( 1 - j ) \cdot {I}_{SC\_ST} ) / Is ) \qquad ( 4 )$$

The voltage difference is calculated by subtracting equation 4 from equation 3 to acquire the following equation 5.

$${V}_{p} - {V}_{OP\_ST} = {n}_{f} \cdot 0.026 \cdot ln ( p ) \qquad ( 5 )$$

Therefore, the following equation 6 can be derived. S1203 uses this equation 6.

$${V}_{p} = ( {V}_{p} - {V}_{OP\_ST} ) + {V}_{OP\_ST} = {n}_{f} \cdot 0.026 \cdot ln ( p ) + {V}_{OP\_ST} \qquad ( 6 )$$

### First Embodiment: Derivation of Calculation Equation at S1208

The following equation 13 expresses I_{SC} at temperature T.

$${I}_{SC} = ( {I}_{PE} / j ) / p \qquad ( 13 )$$

The following equation 14 is acquired by returning I_{SC} to I_{SC}0 at room temperature.

$${I}_{SC} 0 = ( ( {I}_{PE} / j ) / p ) \cdot ( 1 + α \cdot ( 298 - T ) / 100 ) \qquad ( 14 )$$

Therefore, the following equation 15 expresses I_{P0}. S1208 uses this equation 15.

$${I}_{P 0} = {I}_{SC} 0 \cdot j = j \cdot ( ( {I}_{PE} / j / p ) \cdot ( 1 + α \cdot ( 298 - T ) 100 \qquad ( 15 )$$

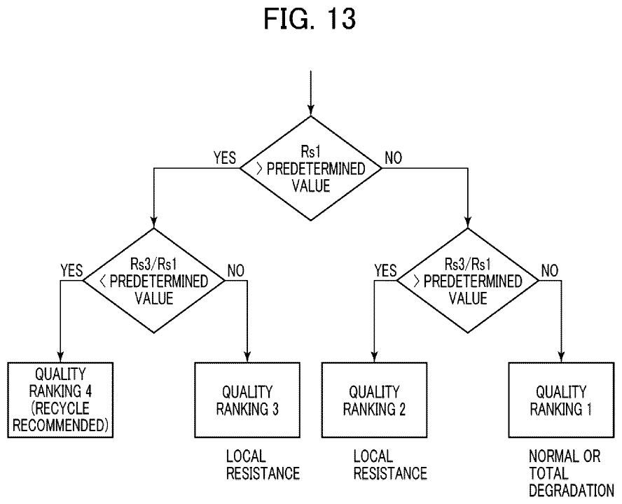

FIG. 13 is a flowchart explaining the procedure for a control device 100 to rank the quality of the solar cell based on the solar cell diagnosis result. The normal state or uniform degradation is determined if Rs1 is smaller than or equal to the first threshold and Rs3/Rs1 is smaller than or equal to the second threshold. The series resistance is determined to slightly increase locally if Rs1 is smaller than or equal to the first threshold and Rs3/Rs1 is greater than the second threshold. The series resistance is determined to increase locally if Rs1 is greater than the first threshold and Rs3/Rs1 is greater than or equal to the third threshold. Recycling is recommended if Rs1 is greater than the first threshold and Rs3/Rs1 is smaller than the third threshold.

In FIG. 13, Rs3/Rs1 may be replaced by a difference found by subtracting Rs1 from Rs3, or, for example, Rs1 may be replaced by Rs2 if Rs1 and Rs2 are approximately the same values.

### Second Embodiment

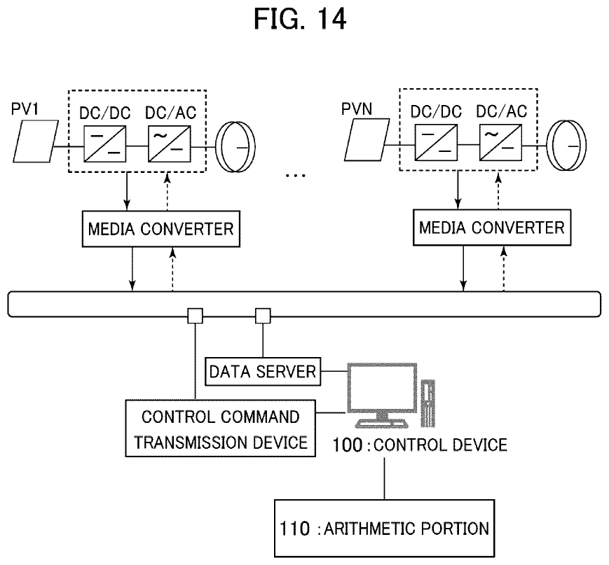

FIG. 14 is a configuration diagram of a solar cell system according to a second embodiment of the present invention. A power conditioner drives one or more solar cells to configure the solar cell system. The control device 100 (degradation factor estimation device) controls the solar cells by controlling the power conditioner. The control device 100 can be configured by a computer, for example. The control device 100 includes an arithmetic portion 110. The arithmetic portion 110 performs the procedures for estimating the degradation factors of the solar cell, as described in the embodiments above.

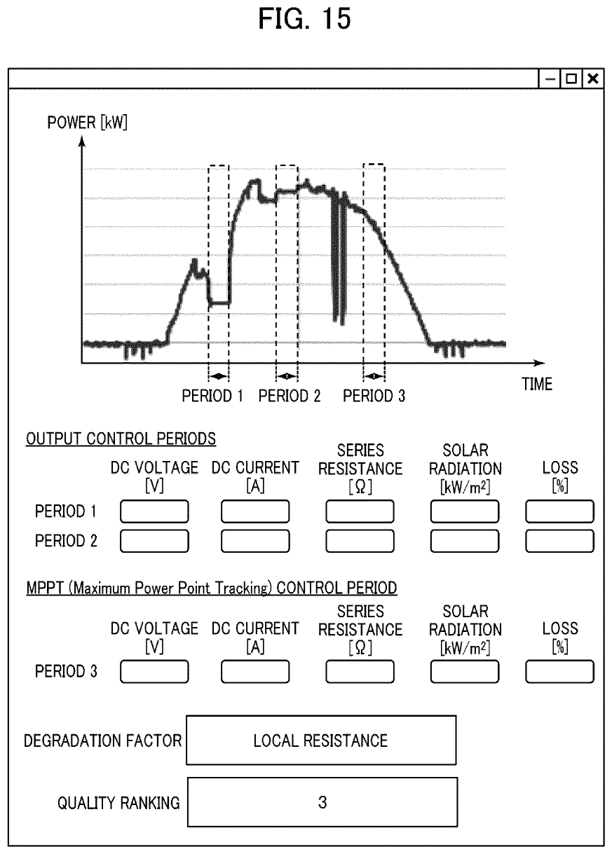

FIG. 15 is an example screen as a user interface provided by the control device 100. The user interface can present time-dependent changes in the solar cell output and the diagnosis results and the ranking results described in the first embodiment, for example.

### Modification of Present Invention

It should be noted that the present disclosure is not limited to the embodiments described above, and includes various modifications. For example, the embodiments described above have been described in detail to simply describe the present disclosure, and are not necessarily required to include all the described configurations. In addition, part of the configuration of one embodiment can be replaced with the configurations of other embodiments, and in addition, the configuration of the one embodiment can also be added with the configurations of other embodiments. In addition, part of the configuration of each of the embodiments can be subjected to addition, deletion, and replacement with respect to other configurations.

In the above embodiments, the arithmetic portion 110 can be configured as hardware such as a circuit device installed with the functions, or can be configured as software installed with the functions that are implemented by an arithmetic device such as a CPU (Central Processing Unit).

### LIST OF REFERENCE SIGNS

11: solar cell string
12: solar cell module
14: solar cell
100: control device
110: arithmetic portion

1. A degradation factor estimation device to estimate degradation factors of a solar cell, comprising:
an arithmetic portion to estimate degradation factors of the solar cell,
wherein the arithmetic portion acquires a first series resistance of the solar cell when the solar cell limits output based on a first amount of solar radiation;
wherein the arithmetic portion acquires as a maximum power point resistance, series resistance of the solar cell when the solar cell tracks the maximum power point; and
wherein the arithmetic portion uses the first series resistance and the maximum power point resistance to diagnose whether a degradation factor of the solar cell is a local increase in series resistance or a total increase in series resistance.

2. The degradation factor estimation device according to claim 1,
wherein the arithmetic portion acquires a first loss of the solar cell when the solar cell limits output based on the first amount of solar radiation;
wherein the arithmetic portion acquires a second loss of the solar cell when the solar cell limits output based on a second amount of solar radiation that is greater than the first amount of solar radiation;
wherein the arithmetic portion diagnoses that a degradation factor of the solar cell is caused by an increase in series resistance when the second loss is greater than the first loss; and
wherein the arithmetic portion diagnoses that a degradation factor of the solar cell is not caused by an increase in series resistance when the second loss is smaller than or equal to the first loss.

3. The degradation factor estimation device according to claim 1,
wherein the arithmetic portion diagnoses that a degradation factor of the solar cell is caused by a local increase in series resistance when the maximum power point resistance is greater than the first series resistance; and
wherein the arithmetic portion diagnoses that a degradation factor of the solar cell is caused by a total increase in series resistance when the maximum power point resistance is smaller than or equal to the first series resistance.

4. The degradation factor estimation device according to claim 1,
wherein the arithmetic portion acquires a second series resistance of the solar cell when the solar cell limits output based on a second amount of solar radiation that is greater than the first amount of solar radiation;
wherein the arithmetic portion diagnoses that a degradation factor of the solar cell is caused by an increase in series resistance when the maximum power point resistance is greater than the first series resistance and is greater than the second series resistance; and
wherein the arithmetic portion diagnoses that a degradation factor of the solar cell is caused by a total increase in series resistance when at least one of the following is true: the maximum power point resistance is smaller than or equal to the first series resistance, or the maximum power point resistance is smaller than or equal to the second series resistance.

5. The degradation factor estimation device according to claim 1,
wherein the arithmetic portion diagnoses a quality rank of the solar cell based on a result of comparing the first series resistance with the maximum power point resistance.

6. The degradation factor estimation device according to claim 1,
wherein the arithmetic portion outputs a diagnostic result recommending recycling of the solar cell when the first series resistance is greater than a first threshold value and a ratio of the maximum power point resistance to the first series resistance, or a difference acquired by subtracting the first series resistance from the maximum power point resistance is smaller than a second threshold value.

7. The degradation factor estimation device according to claim 1,
wherein the arithmetic portion acquires a second series resistance of the solar cell when the solar cell limits output based on a second amount of solar radiation that is greater than the first amount of solar radiation; and
wherein the arithmetic portion outputs a diagnostic result recommending recycling of the solar cell when the second series resistance is greater than a third threshold and a ratio of the maximum power point resistance to the second series resistance or a difference acquired by subtracting the second series resistance from the maximum power point resistance is smaller than a fourth threshold.

8. The degradation factor estimation device according to claim 1,
wherein the arithmetic portion acquires, as the first series resistance, series resistance of the solar cell in a voltage region in which a value acquired by differentiating an output current of the solar cell with an output voltage of the solar cell is negative, and a value acquired by differentiating output power of the solar cell with the output voltage is negative.

9. The degradation factor estimation device according to claim 1,
wherein the arithmetic portion acquires, as the maximum power point resistance, series resistance of the solar cell in a voltage region where a value acquired by differentiating an output current of the solar cell with an output voltage of the solar cell is negative and a value acquired by differentiating output power of the solar cell with the output voltage is within a predetermined range around 0.

10. The degradation factor estimation device according to claim 1,
wherein the arithmetic portion uses an assumed value of the first series resistance to convert an output current of the solar cell and an output voltage of the solar cell into a converted standard voltage and a converted standard current, which are values applicable when the solar cell is assumed to operate at a standard temperature; and
wherein the arithmetic portion calculates the first series resistance by repeating the conversion while varying assumed values for the first series resistance until convergence of difference between the converted standard current and a standard current of the solar cell operating based on the standard amount of solar radiation and the standard temperature.

11. A degradation factor estimation method for estimating degradation factors of a solar cell, comprising:
acquiring a first series resistance of the solar cell when the solar cell limits output based on a first amount of solar radiation;
acquiring, as a maximum power point resistance, series resistance of the solar cell when the solar cell follows a maximum power point; and
using the first series resistance and the maximum power point resistance to diagnose whether a degradation factor of the solar cell is a local increase in series resistance or a total increase in series resistance.
